(19) United States
(12) Patent Application Publication
(10) Pub. No.: US 2026/0243814 A1
(43) Pub. Date: Aug. 20, 2026

(54) A METHOD OF DETECTING A FAULT IN A TRANSMISSION LINE IN AN AC POWER TRANSMISSION SYSTEM

(71) Applicant: Hitachi Energy Ltd, Zürich (CH)

(72) Inventor: Zoran GAJIC, Vasteras (SE)

(21) Appl. No.: 19/157,549

(22) PCT Filed: Mar. 22, 2023
(86) PCT No.: PCT/EP2023/057277

§ 371 Date: Aug. 18, 2025

(51) Int. Cl. G01R 31/08

(52) U.S. Cl. CPC G01R 31/085; G01R 31/088

(57) ABSTRACT

The present disclosure relates to a method of detecting a fault in a transmission line in an alternating current (AC) power transmission system. The method comprises: measuring, at a first measurement point of the transmission line, first phase voltages and first phase currents; obtaining, for the transmission line from the first measurement point to a reach point at a distance from the first measurement point, a shunt factor, which comprises at least one of a shunt impedance and a shunt admittance, between the transmission line and ground; estimating voltages and currents for the reach point on basis of a plurality of system parameters comprising the first phase voltages, the first phase currents, and the shunt factor; and determining whether a fault has occurred or not on basis of at least one of the estimated voltages and the estimated currents.

### TECHNICAL FIELD

The present disclosure relates to a method of detecting a fault in a transmission line in an alternating current, AC, power transmission system and a fault detection system for an AC power transmission system.

### BACKGROUND

In an AC power transmission system, such as a high voltage (HV) or a medium voltage (MV) power transmission system, there is a risk for major short-circuit faults, e.g. from a phase to ground or between phases. Such faults have to be detected and remedied as soon as possible. Therefore, the transmission lines are monitored. Prior art solutions typically utilize measurements of current or impedance. They have shortcomings. In particular for long transmission lines they give uncertain decisions due to inaccurate calculations.

### SUMMARY

In view of the above, it is an object of the present disclosure to provide an improved method of detecting faults on the protected line.

To achieve this object, and also other objects that will be evident from the following description, a method as defined in claim 1 is provided according to the present disclosure. Preferred variants of the method will be evident from the dependent claims.

More specifically, there is provided, according to a first aspect of the present disclosure, a method of detecting a fault in a transmission line in an alternating current, AC, power transmission system, the method comprising: measuring at a first measurement point of the transmission line, first phase voltages and first phase currents;
obtaining, for the transmission line from the first measurement point to a reach point at a distance from the first measurement point, a shunt factor, which comprises at least one of a shunt impedance and a shunt admittance, between the transmission line and ground;
estimating voltages and currents for the reach point on basis of a plurality of system parameters comprising the first phase voltages, the first phase currents, and the shunt factor; and
determining whether a fault has occurred or not on basis of at least one of the estimated voltages and the estimated currents. By taking the shunt factor into account when estimating the voltages and currents for the reach point, the voltage and current estimates become considerably more reliable and close to the actual values at the reach point.

It should be noted that the term Factor is understood as a common term for both impedance and admittance.

The shunt factor may comprise at least one of a shunt factor directly between the transmission line and ground, and a shunt factor of at least one shunt reactor connected with the transmission line. Shunt reactors, which can be fixed or variable, are commonly used on long transmission lines and are connected between the transmission line and ground. The transmission line as such interact capacitively with the ground, i.e. as if it comprises capacitors connected between the transmission line and ground. Depending on how their properties impact the estimation one or both of the line generated factor and the reactor generated factor may, thus, be included.

The plurality of system parameters may further comprise a length of the transmission line from the first measurement point to the reach point, and a line impedance for the transmission line as such. The line impedance primarily comprises inductive reactance, but resistance may be included as well.

The operation of estimating may comprise determining a first matrix having matrix parameters determined on basis of the length of the transmission line, the line impedance and the shunt factor, and multiplying the first matrix with a second matrix having matrix parameters based on the first phase voltages and first phase currents.

Further, the estimation may comprise determining, on basis of the first phase voltages and first phase currents, first sequence voltage components and first sequence current components thereof, thereby estimating the voltages and currents for the reach point as sequence voltage components and sequence current components.

The method may further comprise measuring, at the reach point, second phase voltages and second phase currents.

The operation of determining whether a fault has occurred or not may comprise at least one of comparing the second voltages with the estimated voltages, comparing the second currents with the estimated currents, and comparing power values, determined by means of the second voltages and second currents, with estimated power values, determined by means of the estimated voltages and currents.

The method may further comprise estimating sequence power components at the reach point on basis of the sequence voltage component estimates and the sequence current component estimates, said determining whether a fault has occurred or not being based on at least one of the sequence power components at the reach point.

The method may further comprise determining delta sequence power components at the reach point by means of the sequence power components at the reach point, wherein each delta sequence power component is a difference between a present sequence power component and a previous sequence power component;
determining a delta power value of a combination of the negative sequence power component at the reach point and the zero sequence power component at the reach point;
said determining whether a fault has occurred or not comprising determining whether the positive sequence delta power value is smaller than the delta power value of the combination.

The operation of estimating may comprise determining a phasor for each phase voltage and each phase current and performing the operations in phasor domain.

According to another aspect of the present disclosure there is provided a fault detection system for an alternating current, AC, power transmission system comprising a transmission line, a current and voltage measurement device, the fault detection system comprising at least one intelligent electric device, IED, connectable with the transmission line, wherein a first IED of the at least one IED is configured to:
1 measure first phase voltages and first phase currents at a first measurement point of the transmission line;

obtain, for the transmission line from the first measurement point to a reach point at a distance from the first IED, a shunt factor between the transmission line and ground;

estimate, for the reach point, voltages and currents on basis of the first phase voltages, the first phase currents, the length of the transmission line, the line impedance and the shunt factor; and determine whether a fault has occurred or not on basis of at least one of the estimated voltages and the estimated currents.

The shunt factor may comprise at least one of a shunt factor directly between the transmission line and ground, and a shunt factor of at least one shunt reactor connected with the transmission line.

The fault detection system may comprise a second IED of the at least one IED positioned at the reach point, wherein the second IED is configured to measure second phase voltages and second phase currents at the reach point.

The first IED may be configured to additionally obtain a length of the transmission line from the first measurement point to the reach point, and a line impedance for the transmission line as such. Further, the first IED may be configured to, in conjunction with the estimation of the voltages and currents at the reach point, determine a first matrix having matrix parameters determined on basis of the length of the transmission line, the line impedance and the shunt factor, and multiply the first matrix with a second matrix having matrix parameters based on the first phase voltages and first phase currents. According to a further aspect of the present disclosure there is provided a computer program product comprising instructions which, when downloaded into an intelligent electronic device, IED, connectable to a transmission line of a power transmission system, cause the intelligent electronic device to carry out operations comprising:
measuring values of first phase voltages and first phase currents at a first measurement point of the transmission line;
obtaining, for the transmission line from the first measurement point to a reach point at a distance from the IED, a shunt factor between the transmission line and ground;
estimating, for the reach point, voltage estimates and current estimates on basis of the first phase voltages, the first phase currents, and the shunt factor; and
determining whether a fault has occurred or not on basis of at least one of the voltage estimates and the current estimates.

### BRIEF DESCRIPTION OF THE DRAWINGS

The present disclosure will by way of example be described in more detail with reference to the appended drawings, which show example embodiments of the disclosure.

FIG. 1 schematically illustrates some basic parts of a transmission system.

FIG. 2 is a schematic flow chart of the method according to the present disclosure.

FIG. 3 schematically illustrates a transmission line model.

FIG. 4 schematically illustrates a shunt-reactor arrangement.

FIG. 5 schematically illustrates sequence voltage profiles occurring in the transmission system when different kinds of faults have occurred.

FIG. 6 schematically illustrates calculated sequence voltages in the transmission system when different kinds of faults have occurred between a measurement position and a reach point.

FIG. 7 illustrates phase angle differences for different fault situations.

FIG. 8 illustrates a computer program product.

FIG. 9 is a diagram of a voltage along the transmission line.

FIG. 10 is a diagram of a current along the transmission line.

FIG. 11 is an operate-restraint diagram of currents.

### DETAILED DESCRIPTION

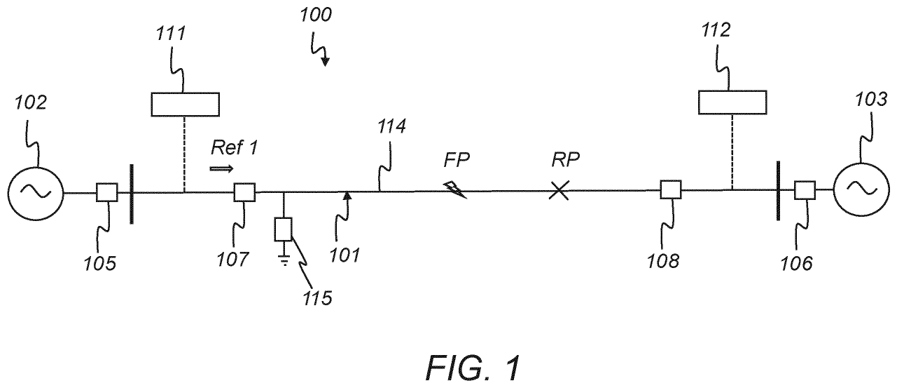

FIG. 1 shows a most general example of an AC power transmission system 100 comprising a transmission line 101, typically having three phases, and at least two ends. In the illustrated example there are two ends. An electrical apparatus 102, 103 is connected to the transmission line 101 at each end thereof. The electrical apparatus 102, 103 may be an electrical source or an electrical load. It can be the grid as well. The transmission line 101 is provided with one or more switching devices 105, 106, 107, 108 allowing restriction of the flow of current in the power transmission system 100. A fault detection system for the AC power transmission system 100 comprises one or more Intelligent Electrical Devices (IEDs) 111, 112. Each IED 111, 112 is connected to the transmission line 101, typically at an end thereof, either directly or via some other device, and is arranged to monitor the electrical activity in the transmission line 101, for instance by means of measuring currents and voltages in the transmission line 101 and using the measurements to detect abnormalities. Therefore, for the purposes of this disclosure, the location at the transmission line 101 where an IED 111, 112 is connected is called a measurement point. Furthermore, the IED 111, 112 is arranged to detect a fault in the transmission line 101 and is arranged to switch one or more of the switching devices 105-108. It should be noted that the transmission line 101, or a portion thereof, that is monitored by the IED 111, 112 is defined as a protected line 114.

As understood by the person skilled in the art the overall structure of the power transmission system shown in FIG. 1 is a mere example among an almost infinite number of different variants. To give just a brief view of the variety, and in addition to what has been described above, the power transmission system may be a part of or connected to the grid, the power sources may be different kinds of power sources such as wind power plants, solar power plants, nuclear power plants, a transformer, etc., the loads may be different kinds of loads such as a production site, etc. The power transmission system may comprise a plurality of transmission lines, etc. The transmission line may be an HV AC line or an MV AC line, it may extend between power sources, between a power source and a load, etc., and, thus, as recognized above, it may constitute what is also referred to as a distribution line. Further, the transmission line may be, for instance, a power cable or an overhead line. The length of the transmission line may vary to a large extent, from a few kilometers, or even shorter, up to hundreds of kilometers.

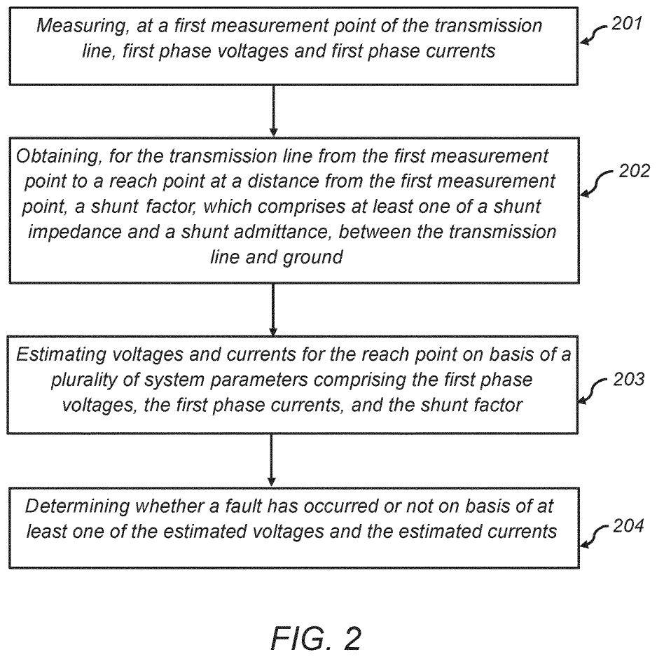

According to exemplifying embodiments of the present method of detecting a fault in the AC power transmission system, the method comprises operations as illustrated in the flow chart of FIG. 2. In a box 201, first phase voltages and first phase currents are measured at a first measurement point. The first phase voltages and currents may be for the three phases of the AC power transmission system 100. The first measurement point is where the first IED 111 is connected to the transmission line 101.

The method further comprises, in box 202, obtaining, for the transmission line 101 from the first measurement point to a reach point RP at a distance from the first measurement point, a shunt factor, which comprises at least one of a shunt impedance and a shunt admittance, between the transmission line 101 and ground. The reach point RP is a chosen location at the transmission line 101 where electric properties of transmission line 101 is going to be estimated in order to be able to decide whether a fault has occurred somewhere along the transmission line 101. The reach point RP may be the remote end of the protected line 114 as seen from the first IED 111, but it may be closer to the first IED 111 as well as beyond the protected line 114. Typical locations for the reach point, depending on what kinds of fault detection, or protection functions, to perform, are at 80%, 100% or 120% of the protected line 114. Thus, the reach point RP can be chosen as desired for the protection purposes. The shunt factor is related to shunt effects such as capacitive impedance which occurs between the transmission line 101 and ground along the transmission line 101, and inductive admittance caused by variable or fixed shunt reactors 115 connected to the transmission line 101 in order to absorb reactive power and thereby increase the efficiency of the AC power transmission system 100. These shunt effects cause charging currents negatively affecting the phase currents of the transmission line 101. At least one of the shunt effects is taken into account for the shunt factor. Typically, the actual value of the shunt factor is obtained from predetermined tables for the transmission line and shunt reactors 115 as will be exemplified below.

On basis of a plurality of system parameters, which comprise the first phase voltages, the first phase currents, and the shunt factor, voltages and currents are estimated for the reach point, box 203. In the following those voltages and currents will be referred to as estimated voltages and estimated currents, or estimated voltages and currents at reach point. At each point also being shortened to @RP. The plurality of system parameters may comprise further parameters as will be evident below.

The method further, in box 204, comprises determining whether a fault has occurred or not on basis of at least one of the estimated voltages and the estimated currents. There are several different kinds of faults that can determined, as will be exemplified below. The determination may include comparisons between the estimations and thresholds, intervals, etc., as well as comparisons between the estimations as such or combinations of them. Furthermore, the estimations may be used to determine other parameters, which are, in turn, used for comparisons. For instance, power values can be determined by means of values of the estimated voltages and currents at reach point. Examples will be given below.

According to embodiments of the method, the plurality of system parameters additionally comprises a length of the transmission line from the first measurement point to the reach point, and a line impedance for the transmission line as such. They are predetermined and, for instance, they are used to obtain the total shunt factor for the whole transmission line 101 between the first measurement point and the reach point RP.

The estimation may employ a matrix notation in order to facilitate the actual calculations that are made, by comprising determining a first matrix having matrix parameters determined on basis of the length of the transmission line, the line impedance and the shunt factor, and multiplying the first matrix with a second matrix having matrix parameters based on the first phase voltages and first phase currents. Furthermore, in order to facilitate the actual calculations, a phasor notation may be employed for the currents and voltages, and sequence components thereof may be determined for positive, negative and zero sequence. In other words, the estimation on basis of the plurality of system parameters includes determining phasors for all of the first phase voltages and first phase currents, for instance by sampling the measured first phase voltages and first phase currents, and applying a discrete Fourier transform, DFT, filter, or some other kind of appropriate filtering. Then the sequence components for the first phase currents and the first phase voltages of a three-phase transmission line can be determined by matrix calculations according to:

$$( \begin{matrix}{I}_{0} \\ {I}_{1} \\ {I}_{2}\end{matrix} ) = \frac{1}{3} * ( \begin{matrix}1 & 1 & 1 \\ 1 & a & {a}^{2} \\ 1 & {a}^{2} & a\end{matrix} ) * ( \begin{matrix}{I}_{A} \\ {I}_{B} \\ {I}_{C}\end{matrix} ) \qquad Eqn . 1 and 2$$

$$( \begin{matrix}{U}_{0} \\ {U}_{1} \\ {U}_{2}\end{matrix} ) = \frac{1}{3} * ( \begin{matrix}1 & 1 & 1 \\ 1 & a & {a}^{2} \\ 1 & {a}^{2} & a\end{matrix} ) * ( \begin{matrix}{U}_{A} \\ {U}_{B} \\ {U}_{C}\end{matrix} )$$

where the three phases are indexed by A, B, and C, and the positive, negative and zero sequences are indexed by 1, 2, and 0, respectively. The factor a is a complex operator, such that a=e^{j*120°}, and j²=−1. Consequently, I₀, I₁, I₂ represent the sequence current components for the zero, positive, and negative sequences, and U₀, U₁, U₂, represent the sequence voltage components for the zero, positive, and negative sequences.

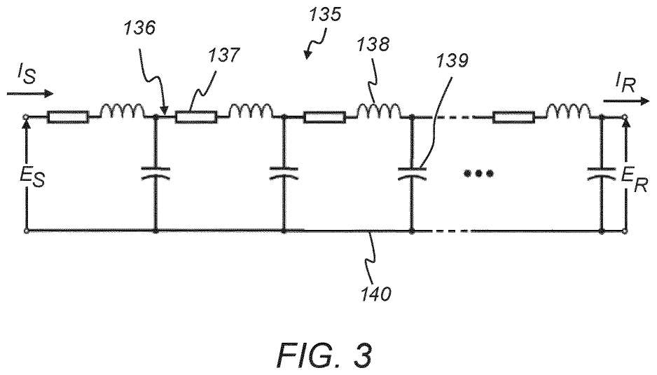

For a general transmission line there is a transmission line model 135, which has a line impedance represented by series connected resistors 137 and inductors 138 along, and inherent of, the transmission line 136, and shunt capacitors 139 between the transmission line 136 and a parallel line 140, which for instance can be ground, as shown in FIG. 3. A two-port network model can be applied on the transmission line model 135. The two-port network is a model of any electric network or device which has two pairs of terminals which can be connected to external equipment, and is represented by a black box having a first port with two terminals on one side of the black box, and another port with two terminals on the opposite side of the black box. For the transmission line model, the two-port equation on matrix notation becomes:

$$[ \begin{matrix}{E}_{S} \\ {I}_{S}\end{matrix} ] = [ \begin{matrix}A & B \\ C & D\end{matrix} ] ⋆ [ \begin{matrix}{E}_{R} \\ {I}_{R}\end{matrix} ] \qquad Eqn . 3$$

E_{S} and I_{S} are sending line end voltage and current phasor pair for either positive, negative, or zero sequence. E_{R} and I_{R} are receiving line end voltage and current phasor pair for the same sequence. Referring to the present disclosure, the sending line end voltage and current phasor pair E_{S} and Is correspond with the sequence voltage components U₀, U₁, U₂ and the sequence current components I₀, I₁, I₂ of the first phase voltages and the first phase currents measured at the first IED 111. Similarly, the receiving line end voltage and current phasor pair E_{R} and I_{R} correspond with the estimated sequence voltage and current components at the reach point U₀@RP, U₁@RP, U₂@RP, I₀@RP, I₁@RP, I₂@RP. A, B, C, and D are complex parameters, and they are fixed complex numbers for a particular line and a selected reach point. By simple mathematical manipulations the matrix equation can be rearranged to adapt to the present purposes, that is the estimation, as follows:

$$[ \begin{matrix}{E}_{R} \\ {I}_{R}\end{matrix} ] = [ \begin{matrix}A & - B \\ - C & D\end{matrix} ] ⋆ [ \begin{matrix}{E}_{S} \\ {I}_{S}\end{matrix} ] \qquad Eqn . 4$$

Thereby, the ABCD matrix corresponds with the above-mentioned first matrix, and the matrix with parameters E_{S} and I_{S} corresponds with the above-mentioned second matrix, while the matrix with parameters E_{R} and I_{R} contains the estimated sequence voltage and sequence current components for the sequence being processed. However, this is merely true if the impact of shunt reactors is not taken into account, which is a possibility within the scope of the present disclosure. On the other hand, when shunt reactors are present in the AC power transmission system 100, it is advantageous to include them when estimating the voltages and currents for the reach point RP. This will be further described below.

The following formulas can be used to calculate the matrix ABCD parameters for the transmission line itself:

$$A = cosh ( d * \sqrt{{z}^{′} * {y}^{′}} ) \qquad Eqn . 5$$

$$B = \sqrt{\frac{{z}^{′}}{{y}^{′}}} * sinh ( d * \sqrt{{z}^{′} * {y}^{′}} ) \qquad Eqn . 6$$

$$C = \sqrt{\frac{{y}^{′}}{{z}^{′}}} * sinh ( d * \sqrt{{z}^{′} * {y}^{′}} ) \qquad Eqn . 7$$

$$D = A \qquad Eqn . 8$$

where z′ is a series impedance per unit length of the transmission line, i.e. Z/LineLength in Ω/km where Z is the line impedance in Ohms;
y′ is admittance to ground per unit length of the transmission line, i.e.
Y/LineLength in Siemens/km, where Y is the total shunt admittance in Siemens;
LineLength is the length of the transmission line being protected in km; and d is the distance from the first measurement point to the Reach Point RP.

It should be noted that these ABCD parameters have fixed complex values for a specified Reach Point and that they can be easily calculated off-line, and predetermined. Two sets of such matrix parameters are typically needed for a transmission line. One ABCD-parameter set represents the transmission line network model for positive and negative sequence, and the other ABCD-parameter set represents the transmission line network model for zero sequence. Once these ABCD parameters have been obtained corresponding 2×2 matrixes for the transmission line can be established. In a real situation, typically all the required data is readily available, in form of predetermined tables of relevant values. Further, it is to be noted that when two or more two-port networks are interconnected, i.e., connected in series such that an output port of one two-port network is connected with an input port of another two-port network, their ABCD matrices are multiplied with each other.

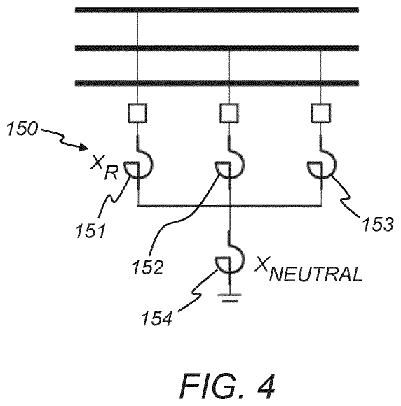

Shunt reactors 115 are commonly used on long Overhead Lines, OHLs, and cables in order to compensate for the reactive power generated by the shunt capacitances, represented by the shunt capacitors 139 in the model 135, of the transmission line 101. A commonly used shunt-reactor arrangement 150 in HV systems is shown in FIG. 4. The arrangement has four shunt reactors 151-154, one for each phase line, and a fourth shunt rector 154 connected to all the other three shunt reactors 151-153 and to ground. However, the fourth shunt reactor 154, called neutral reactor, is only used on OHLs where single pole auto-reclosing is used. It is typically not used in power cable applications. This shunt-reactor arrangement 150 is one example of the most schematic general shunt reactor 115 indicated in FIG. 1.

The sequence impedances of such a shunt reactor are:
X₁=X₂=X_{R} Positive and negative sequence reactance; and
X₀=X_{R}+3*X_{NEUTRAL} Zero sequence reactance.

In case the fourth, neutral reactor is not used the zero-sequence reactance is equal to the positive sequence reactance X₁. Applying the two-port network model to the shunt reactor renders two ABCD matrices as follows:

$$[ \begin{matrix}{A}_{1} & {B}_{1} \\ {C}_{1} & {D}_{1}\end{matrix} ] = [ \begin{matrix}1 & 0 \\ 1 / jX 1 & 1\end{matrix} ] \qquad Eqn . 9$$

$$[ \begin{matrix}{A}_{0} & {B}_{0} \\ {C}_{0} & {D}_{0}\end{matrix} ] = [ \begin{matrix}1 & 0 \\ 1 / jX 0 & 1\end{matrix} ] \qquad Eqn . 10$$

where the matrix parameters A₁, B₁, C₁, D₁ form the ABCD matrix for the positive sequence. As mentioned above, the ABCD matrix for the negative sequence is equal to the ABCD matrix for the positive sequence.

Correspondingly, the matrix parameters A₀, B₀, C₀, D₀ form the ABCD matrix for zero sequence. As mentioned above, if the neutral shunt reactor is not used, then the ABCD matric for zero sequence is equal to those for positive and negative sequence. It can be noted that the C parameter, 1/jX, is an admittance.

The shunt reactor 115 can have a fixed reactor impedance. However, alternatively it can have a variable impedance, which depends on the used tap position for the variable shunt reactor. Such a variable impedance is readily coped with in the matrix operations. Typically, the reactor values for different tap positions are obtainable from a predetermined table.

It is to be noted that other impedance or admittance components can be modelled in a similar way, such as e.g. series capacitors of the transmission line, as will be understood by the person skilled in the art from the present description.

Referring to the present method, as mentioned above, when estimating the voltages and currents at the reach point RP, it is advantageous to take into account both properties associated with the transmission line 101 as such, and properties associated with external elements, like the shunt reactors 115, not just one of them. With the matrix notation this can be done by matrix multiplication, as mentioned above for interconnected two-port networks. Thus, by denoting the ABCD matrix for the transmission line as such MTL, the first matrix MF, the second matrix MS, and the resulting matrix MRP, since it contains parameters for the reach point RP, and further denoting the shunt reactor matrix MSR, the following equation can be employed:

$$MRP = MF ⋆ MS = MTL ⋆ MSR ⋆ MS \qquad Eqn . 11$$

In order to determine the individual parameters of the matrices, properties associated with the transmission line as such, and more particularly the part of the transmission line constituting the protected line, which may very well constitute the whole length of the transmission line between two main connection sites, such as at a wind farm and at the grid, are obtainable from a table, or some other suitable representation, which has been set up in advance. For long transmission lines, e.g. 100 km or 200 km, such a table may contain values for several different sub-sections of the transmission line, simply because it is physically divided in sub-sections. The transmission line may contain different kinds of sub-sections, such as overhead lines, submarine cables, etc. Often, the sub-section values can be added to a total value for the whole length, but if not, a separate ABCD matrix can be determined for each sub-section. These sub-section matrices are then multiplied with each other to form the single matrix MTL for the transmission line. Similarly, by multiplying this transmission line matrix MTL with the shunt reactor matrix MSR finally the first matrix MF representing the whole protected object, i.e. all relevant line sub-sections and associated shunt factors, is generated.

The table of properties can hold, for example, resistance, reactance, and capacitance, all for positive sequence as well as zero sequence. By applying the above equations Eqn. 5-Eqn. 8, the matrix for the transmission line/protected line MTL can be determined. If the estimation of voltages and currents at reach point are going to be made for some other position than the end of the protected line, such as 80% or 120%, as mentioned above, a reach point factor RPF is applied to the length value, such as RPF=0.8 or RPF=1.2.

For the/each shunt reactor 115 predetermined values of reactance are obtained as predetermined data, or reactive power and voltage are noted, from which the reactance is easily obtained. Then the shunt reactor matrices MSR for positive and zero sequences are determined according to the above equations Eqns. 9 and 10.

Then, for positive and zero sequences, the first matrix MF can be determined as the product of the respective transmission line matrix MTL and shunt reactor matrix MSR, i.e. MF=MTL*MSR. Finally, for each sequence, the reach point matrix MRP is determined as the product of the first matrix MF and the second matrix MS, i.e. MRP=MF*MS. Recalling that the first matrix is the same for the positive and negative sequences, the following equations will provide the final estimates of the voltages and currents at reach point for all sequences:

$$[ \begin{matrix}{U}_{1} @ RP \\ {I}_{1} @ RP\end{matrix} ] = [ \begin{matrix}MA 1 & - MB 1 \\ - MC 1 & MD 1\end{matrix} ] * [ \begin{matrix}{U}_{1} \\ {I}_{1}\end{matrix} ] \qquad Eqn . 12$$

$$[ \begin{matrix}{U}_{2} @ RP \\ {I}_{2} @ RP\end{matrix} ] = [ \begin{matrix}MA 1 & - MB 1 \\ - MC 1 & MD 1\end{matrix} ] * [ \begin{matrix}{U}_{2} \\ {I}_{2}\end{matrix} ] \qquad Eqn . 13$$

$$[ \begin{matrix}{U}_{0} @ RP \\ {I}_{0} @ RP\end{matrix} ] = [ \begin{matrix}MA 0 & - MB 0 \\ - MC 0 & MD 0\end{matrix} ] * [ \begin{matrix}{U}_{0} \\ {I}_{0}\end{matrix} ] \qquad Eqn . 14$$

By means of the estimated voltages and currents, and more particularly, their sequence components, U₁@RP, U₂@RP, U₀@RP, I₁@RP, I₂@RP, I₀@RP, in phasor notation, it is possible to execute the operation of determining whether a fault has occurred or not on basis of at least one of the estimated voltages and the estimated currents. There are many kinds of fault, which can be detected, and many ways to perform the detection. Some examples will be given below.

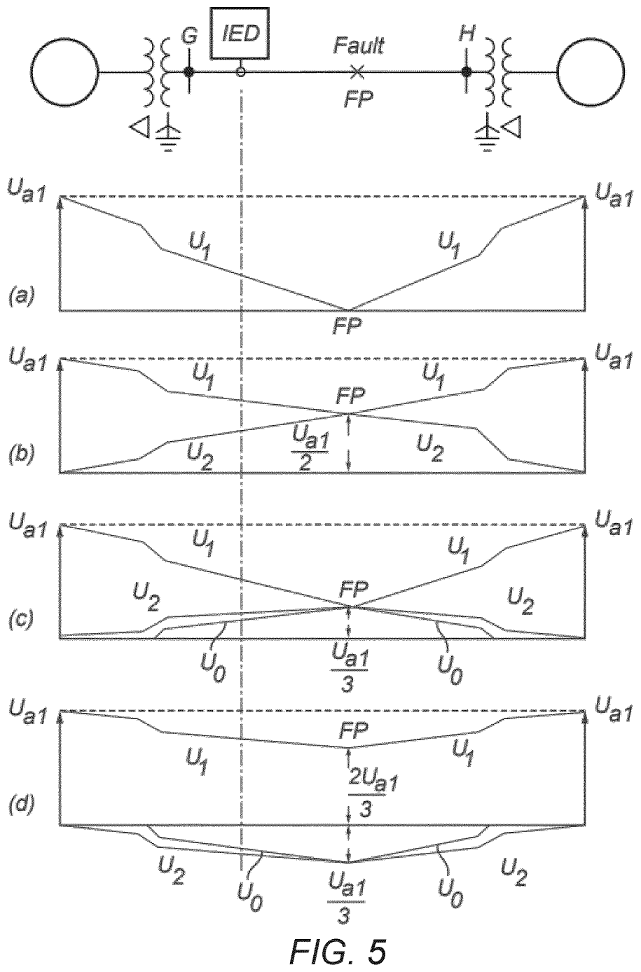

According to one example, the fault detection is based on sequence voltage components. Before continuing it will be explained, in conjunction with FIG. 5 how the sequence voltage components behave when different types of faults occur at a fault point FP along the protected line 114. The top graph shows a three-phase fault, i.e. when all three phases are affected by the same fault. Only the positive sequence voltage component U₁ is non-zero somewhere, but its magnitude is decreasing from a maximum value at the end points to zero at the fault point. In the second to top graph the sequence voltage components at a phase-to-phase, i.e. two-phase, fault are shown. The positive and negative sequence voltage components are present, and at the fault point they are equal. The third to top graph represents a two-phases-to-ground fault, where all three sequence voltage components are non-zero. At the fault point FP they are all equal, the magnitude of the positive sequence voltage component increases from the fault point towards the ends of the protected line, while the magnitudes of the other two sequence voltage components decrease towards the ends. The bottom graph illustrates a phase-to-ground fault.

However, although the estimation of voltages and currents at RP is rather accurate, and better than previous estimations not taking shunt factors into account, it is still an approximation based on mathematical models. Therefore, the estimated sequence voltage components do not quite mirror the actual behaviour as illustrated in FIG. 5, but the result is accompanied by some effects which have to be considered in the fault determination.

The method may further comprise measuring, at the reach point RP, second phase voltages and second phase currents U_{M}@RP, I_{M}@RP. Like with the first phase voltages and first phase currents, phasors and sequence components are determined for the second phase voltages and second phase currents. The sequence voltage components and sequence current components measured at the reach point being denoted U_{M1}@RP, U_{M2}@RP, U_{M0}@RP, I_{M1}@RP, I_{M2}@RP, I_{M0}@RP. The operation of determining whether a fault has occurred or not comprises at least one of comparing the second voltages, i.e. their sequence components U_{M1}@RP, U_{M2}@RP, U_{M0}@RP, with the sequence components of the estimated voltages U₁@RP, U₂@RP, U₀@RP, comparing the second currents with the estimated currents, and comparing power values, determined by means of the second voltages and second currents, with estimated power values, determined by means of the estimated voltages and currents.

As an example, with reference to FIG. 11, a current based line differential protection can be formed which compares the estimated phase currents with the actual measured phase currents at the reach point RP. The estimated phase currents are generated from the estimated sequence current components by reversely applying equations 1 and 2 above. This comparison may for example be done for phase A as follows. The differential current I_Diff_A and a bias current_Bias_A are determined according to:

$$I\_Diff \_A = IA\_Est @ RP + IA\_Mesured @ RP \qquad Eqn . 15$$

$$I\_Bias \_A = max ( IA\_Est @ RP ; IA\_Mesured @ RP )$$

These currents may be entered into an operate-restraint characteristic, as shown in FIG. 11. The operate-restraint characteristic contains a threshold current, called IdMin in the diagram, which marks the border for tripping illustrated with the lower curve 160. Below the threshold current IdMin no tripping of any breaker is initiated, in a restrain area, i.e. the state of the AC power transmission system 100 remains. Above the threshold current IdMin tripping is executed, in an operation area, and the current is broken through the transmission line of the protected object 114 is broken. However, the operation area may be divided in a lower subarea above but in the vicinity of the threshold current where the decision to execute the tripping may rest on one or more additional conditions, and an upper subarea above the lower subarea where the tripping is unconditionally executed. By means of the present method, where the shunt factor is used in the estimation of currents at the reach point RP, it is possible to use a lower threshold than in the prior art where the shunt factor was not used, but only the line impedance. This is because the estimation is more accurate. Consequently, the method is more sensitive than the prior art methods without causing more false fault decisions. In FIG. 11 the upper graph 161 illustrates that in the prior art methods it is necessary to increase the level of the threshold current IdMin in order not to cause false trippings, which are a result of the lower accuracy. On the other hand, when a fault actually occurs a higher threshold current IdMin causes a longer time during which the short current can flow and increase, thereby rendering a higher risk of causing damage to the AC power transmission system 100.

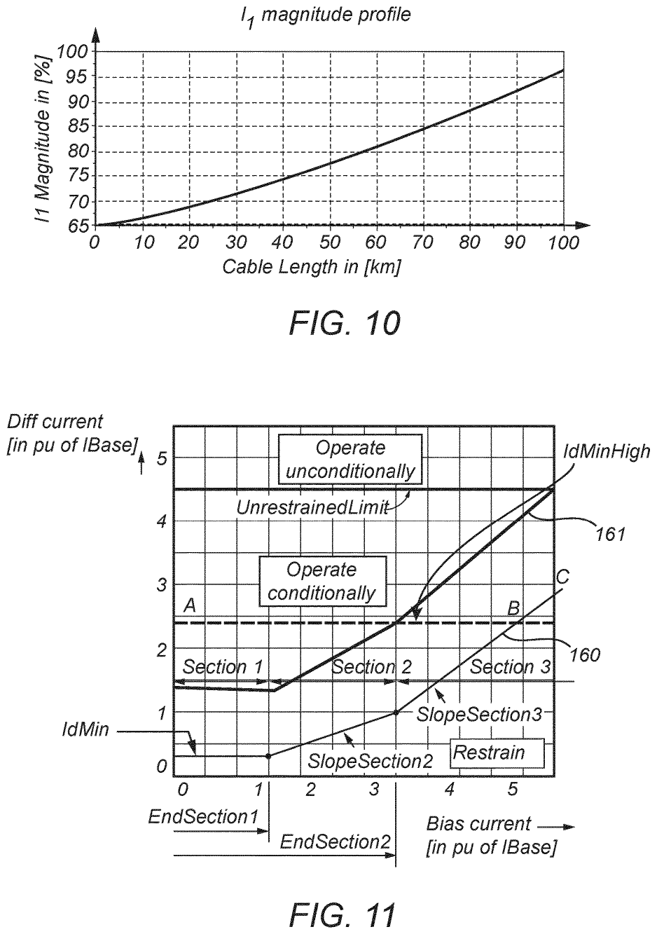

The accuracy difference between the prior art method only taking the line impedance into account is illustrated in FIGS. 9 and 10. The error of the prior art method increases with the length of the transmission line, in particular when the transmission is a cable, while the error is less for transmission lines being overhead lines OHL. FIGS. 9 and 10 illustrate, by a representative example, the impact of adding the shunt factor into the matrix calculations for estimating the voltages and currents at the reach point RP. In FIG. 9 the y axis represents the phase to ground voltage represented by the positive sequence voltage component U₁ in percent of a base voltage corresponding the rated voltage. It can be seen that for the prior art method, the upper graph shown by a broken line, the estimated voltage decreases from 105% to just below 101% from a cable length close to 0 km up to a cable length of 100 km, while for the present method the estimated current decreases from 105% to just below 97% for the same lengths of the cable. Consequently, there is a difference of 4 percentage points, which is a difference small enough to be ignorable. On the other hand, the difference for the current is certainly significant, as can be seen in FIG. 10. When using the prior art method, the estimated current for any length of the cable is the same as the current for a cable close to 0 km long, being 65% of the base current, i.e. the rated current. However, when using the present method the estimated current increases with the length of the cable up to more than 95% of the base current for a cable length of 100 km. This effect is due to the charging current compensation, compensating for charging currents along the transmission line, that is obtained by means of the present method.

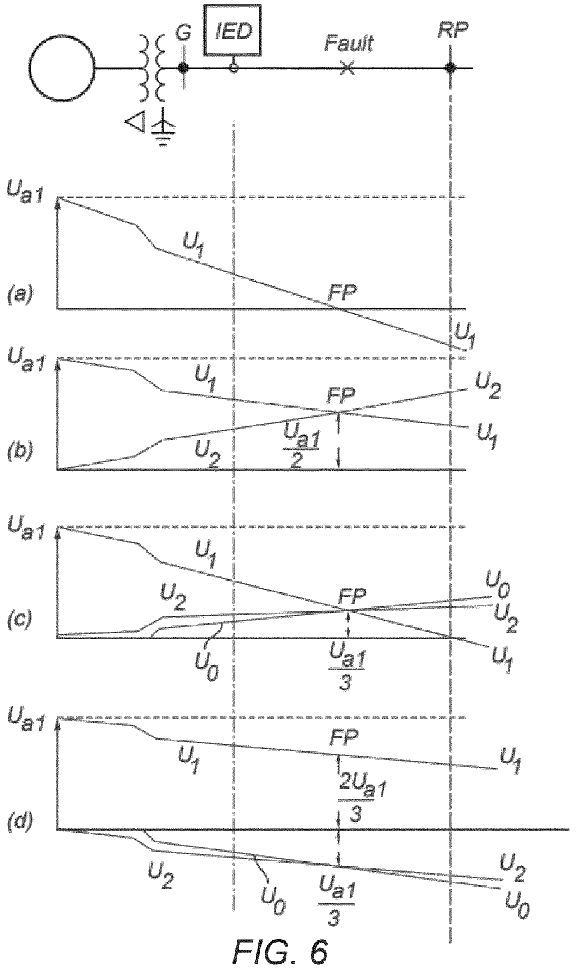

According to another example of the fault determination, it is assumed that the fault occurs at a point between the measurement point at the IED 111 and the reach point RP. Then the estimated sequence voltage components will go through the fault point FP and may change sign, as shown in the upper most graph in FIG. 6. As illustrated in FIG. 5, this does not happen in the real system, it is a result of the estimation. However, that can be accounted for in the determinations of properties of the faults. Some further notes should be made as regards the estimations of the voltage values at the reach point RP as follows:
1) The magnitude of the positive sequence voltage at the reach point RP will be even lower than at the fault point FP when fault location is in-between the IED 111 and the RP. That is not physically possible, i.e. such a location does not exist in the real faulty transmission system 100 but it is caused by the applied estimation.
2) Magnitudes of the negative and zero sequence voltages at the reach point RP will be larger than at the fault point FP when a fault is located in-between the IED 111 and the reach point RP. That is also not physically possible but it is caused by the applied estimation.
3) For a 3-phase fault, i.e. the top most graph, the positive sequence voltage at the reach point U₁@RP will have 180 degrees phase shift from the positive sequence voltage U₁ measured by the IED 111, i.e. it becomes inverted. As already noted above that does not occur in reality.
4) This inversion of the positive sequence voltage can even happen for a 2-phase or even a 1-phase fault if the fault point FP is very close to the IED 111 and the reach point RP is quite remote from the IED 111. However, such positive sequence voltage inversion at the reach point RP also means that the fault is definitely within the set reach of the distance protection, i.e. within the protected zone.

Based on the above information and the estimations of the sequence voltages at the reach point U₁@RP, U₂@RP, U₀@RP it is possible to determine different properties of the protected line related to the faults by means of operating quantities and restraining quantities determined on basis of the sequence voltages.

The operating quantities per phase at the reach point RP, OP_{A}@RP, OP_{B}@RP, and OP_{C}@RP, are determined according to:

$$O {P}_{A} @ RP = {U}_{2} @ RP + {U}_{0} @ RP$$

$${OP}_{B} @ RP = a * {U}_{2} @ RP + {U}_{0} @ RP$$

$${OP}_{C} @ RP = {a}^{2} * {U}_{2} @ RP + {U}_{0} @ RP$$

Thus, the operating quantities OP_{A}@RP, OP_{B}@RP, and OP_{C}@RP are based on a sum of negative and zero sequence voltages. The corresponding restraining quantities at the reach point, RST_{A}@RP, RST_{B}@RP, and RST_{C}@RP are determined according to:

$$R S {T}_{A} @ RP = {U}_{1} @ RP$$

$${RST}_{B} @ RP = {a}^{2} * {U}_{1} @ RP$$

$$RS {T}_{C} @ RP = a * {U}_{1} @ RP$$

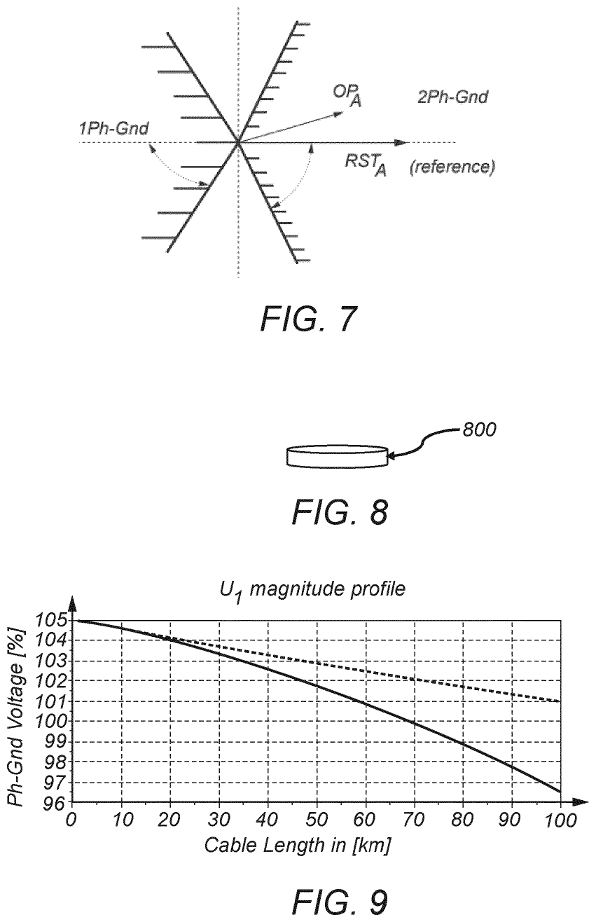

In this example, it is also determined in which phase, or phases, a fault has occurred. A phase angle difference between the operating quantity and the corresponding restraining quantity is determined. However, first it is determined if a magnitude of at least one of the operating quantities OP_{A}@RP, OP_{B}@RP, and OP_{C}@RP exceeds a minimum threshold level, such as for example 5% of the rated phase voltage. If affirmative, which it will be for all unsymmetrical faults, it is decided that a fault has occurred. Then it is determined which operating quantity OP_{A}@RP, OP_{B}@RP, OP_{C}@RP has the largest magnitude. The type of the fault and consequently faulty phases can then be determined by doing a comparison between the phase angles of the Operating and Restraining quantities for the phase having the largest magnitude of the operating quantity. For instance, assume that the operating quantity related to phase A has the largest magnitude, i.e. OP_{A}@RP>OP_{B}@RP AND OP_{A}@RP>OP_{C}@RP. The phase angle comparison is shown in FIG. 7. The comparison can be referred to as a directional comparison. The following principles are valid for this phase angle comparison:
1) If the Operating quantity OP_{A}@RP is approximately in contra-phase from the Restraining quantity RST_{A}@RP, or within an interval thereabout, i.e. the phase angle difference is within an interval around 180 degrees, then the fault is an A-Phase-to-Ground fault (i.e. 1-Phase-to-ground as shown at the left side in the graph in FIG. 7.
2) If the Operating quantity OP_{A}@RP is approximately in phase with the Restraining quantity RST_{A}@RP, or within an interval thereabout, i.e. the phase angle difference is within an interval around 0 degrees, then the fault is a B-C-Gnd fault, i.e. in the other two phases, as shown at the right side of the graph in FIG. 7.

In another example of determining whether a fault has occurred, the estimated sequence voltage and current components at RP U₁@RP, U₂@RP, U₀@RP, I₁@RP, I₂@RP, I₀@RP are employed to determine corresponding sequence power components S₁, S₂, S₀. Then a composite sequence power is determined according to:

$${S}_{Cmp} = {k}_{1} ⋆ {S}_{1} - ( {k}_{2} ⋆ {S}_{2} + {k}_{0} ⋆ {S}_{0} ) \qquad Eqn . 16$$

where k₁, k₂, k₀ are settable non-negative weighting factors. In this example, the method further comprises determining a delta value of the composite sequence power ΔS_{Cmp} as a difference between a present composite sequence power value S_{Cmp} (present) and a previous composite sequence power value S_{Cmp} (previous), according to following equation (Eqn. 17):

$$\begin{matrix}Δ {S}_{Cmp} = {S}_{Cmp} ( present ) - {S}_{Cmp} ( previous ) = Δ {P}_{Cmp} + j * Δ {Q}_{Cmp} \\ = \begin{matrix}( {P}_{Cmp} ( present ) - {P}_{Cmp} ( previous ) ) + \\ j ⋆ ( {Q}_{Cmp} ( present ) - {Q}_{Cmp} ( previous ) )\end{matrix}\end{matrix}$$

Thus, the determination of the delta value of the composite sequence power ΔS_{Cmp} comprises determining an active power delta value ΔP_{Cmp} as a difference between an active power part P_{Cmp} (present) of the present composite sequence power value and an active power part P_{Cmp} (previous) of the previous composite sequence power value, and determining a reactive power delta value ΔQ_{Cmp} as a difference between a reactive power part Q_{Cmp} (present) of the present composite sequence power value and a reactive power part Q_{Cmp} (previous) of the previous composite sequence power value. A fault criterion is based on the delta value of the composite sequence power ΔS_{Cmp}, and if the criterion if fulfilled then it is determined that a fault has occurred.

For instance, the method may further comprise determining a delta value of the composite sequence power ΔS_{Cmp} at both the measurement point, i.e. at the first IED 111, denoted ΔS_{Cmp}@MP and at the reach point RP, denoted ΔS_{Cmp}@RP. The delta value of the composite sequence power at reach point ΔS_{Cmp}@RP comprises an active power delta value at reach point ΔP_{Cmp}@RP, and a reactive power delta value at reach point ΔQ_{Cmp}@RP. Correspondingly, the delta value of the composite sequence power at the measurement point comprises an active power delta value at ΔP_{Cmp}@MP, and a reactive power delta value at the measurement point ΔQ_{Cmp}@MP. If the active power delta values at the different points ΔP_{Cmp}@MP, ΔP_{Cmp}@RP and the first and the second reactive power delta values ΔQ_{Cmp}@MP, ΔQ_{Cmp}@RP are all positive and above a threshold value then a fault has occurred between the two points. The result of these operations may be referred to as a directional comparison, which is a method of determining that the fault has occurred on the protected line 114.

According to another example, it may be determined that the fault has occurred between the measurement point and the reach point if the following equation is fulfilled.

$$Δ {S}_{1} @ RP < Δ {S}_{20} @ RP \qquad Eqn . 18$$

where ΔS₁@RP is a delta sequence power value of the positive sequence power at the reach point, and ΔS₂₀@RP is a delta sequence power value of a combination of the negative sequence power at the reach point and the zero sequence power at the reach point. Thus, when the equation, Eqn. 18, is fulfilled, i.e. when the delta value of the positive sequence power at the reach point ΔS₁@RP is less than the delta value of the combination of the negative sequence power at the reach point and the zero sequence power at the reach point ΔS₂₀@RP, then a fault has been detected where the fault is located between the first measurement point, i.e. at the IED 111, and the reach point RP. For example, the combination may be the whole part of the expression that involves the negative and zero sequence powers and valid for the reach point, which is the negative sum of those powers, i.e. S₂₀@RP=−(S₂@RP+S₀@RP).

FIG. 8 most schematically illustrates that as an aspect of the present disclosure, there is provided a computer program product 800 comprising instructions which, when downloaded into the IED 111 cause the IED 111 to carry out operations comprising:
measuring values of the first phase voltages and first phase currents at the first measurement point of the transmission line 101;
obtaining, for the transmission line 101 from the first measurement point to the reach point RP, the shunt factor;
estimating, for the reach point, voltage estimates and current estimates on basis of the first phase voltages, the first phase currents, and the shunt factor; and determining whether a fault has occurred or not on basis of at least one of the voltage estimates and the current estimates.

While the present disclosure has been illustrated and described in detail in the drawings and foregoing description, such illustration and description are to be considered illustrative or exemplary and not restrictive.

Although features and elements are described above in particular combinations, each feature or element can be used alone without the other features and elements or in various combinations with or without other features and elements.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain features are recited in mutually different dependent claims does not indicate that a combination of these features cannot be used to advantage. Any reference signs in the claims should not be construed as limiting the scope.

1. A method of detecting a fault in a transmission line in an alternating current (AC) power transmission system, the method comprising:
measuring, at a first measurement point of the transmission line, first phase voltages and first phase currents;
obtaining, for the transmission line from the first measurement point to a reach point at a distance from the first measurement point, a shunt factor, which comprises at least one of a shunt impedance and a shunt admittance, between the transmission line and ground;
estimating voltages and currents for the reach point on basis of a plurality of system parameters comprising the first phase voltages, the first phase currents, and the shunt factor; and
determining whether a fault has occurred or not on basis of at least one of the estimated voltages and the estimated currents.

2. The method according to claim 1, wherein the shunt factor comprises at least one of a shunt factor directly between the transmission line and ground, and a shunt factor of at least one shunt reactor connected with the transmission line.

3. The method according to claim 2, wherein the plurality of system parameters further comprises a length of the transmission line from the first measurement point to the reach point, and a line impedance for the transmission line as such.

4. The method according to claim 3, said estimating comprising determining a first matrix having matrix parameters determined on basis of the length of the transmission line, the line impedance and the shunt factor, and multiplying the first matrix with a second matrix having matrix parameters based on the first phase voltages and first phase currents.

5. The method according to claim 1, said estimating comprising determining, on basis of the first phase voltages and first phase currents, first sequence voltage components and first sequence current components thereof, thereby estimating the voltages and currents for the reach point as sequence voltage components and sequence current components.

6. The method according to claim 1, further comprising measuring, at the reach point, second phase voltages and second phase currents.

7. The method according to claim 6, said determining whether a fault has occurred or not comprising at least one of comparing the second voltages with the estimated voltages, comparing the second currents with the estimated currents, and comparing power values, determined by means of the second voltages and second currents, with estimated power values, determined by means of the estimated voltages and currents.

8. The method according to claim 6, further comprising estimating sequence power components at the reach point on basis of the sequence voltage component estimates and the sequence current component estimates, said determining whether a fault has occurred or not being based on at least one of the sequence power components at the reach point.

9. The method according to claim 8, further comprising:
determining delta sequence power components at the reach point by means of the sequence power components at the reach point, wherein each delta sequence power component is a difference between a present sequence power component and a previous sequence power component;
determining a delta power value of a combination of the negative sequence power component at the reach point and the zero sequence power component at the reach point;
said determining whether a fault has occurred or not comprising determining whether the positive sequence delta power value is smaller than the delta power value of the combination.

10. The method according to claim 1, said estimating comprising determining a phasor for each phase voltage and each phase current and performing the operations in phasor domain.

11. A fault detection system for an alternating current (AC) power transmission system comprising a transmission line, the fault detection system comprising at least one intelligent electric device (IED) connectable with the transmission line, wherein a first IED of the at least one IED is configured to:
measure first phase voltages and first phase currents at a first measurement point of the transmission line;
obtain, for the transmission line from the first measurement point to a reach point at a distance from the first IED, a shunt factor, which comprises at least one of a shunt impedance and a shunt admittance, between the transmission line and ground;
estimate voltages and currents for the reach point on basis of a plurality of system parameters comprising the first phase voltages, the first phase currents, and the shunt factor; and
determine whether a fault has occurred or not on basis of at least one of the estimated voltages and the estimated currents.

12. The fault detection system according to claim 11, wherein the shunt factor comprises at least one of a shunt factor directly between the transmission line and ground, and a shunt factor of at least one shunt reactor connected with the transmission line.

13. The fault detection system according to claim 12, wherein a second IED of said at least one IED positioned at the reach point is configured to measure second phase voltages and second phase currents at the reach point.

14. The fault detection system according to claim 11, wherein the first IED is configured to additionally obtain a length of the transmission line from the first measurement point to the reach point, and a line impedance for the transmission line as such, and wherein the first IED in conjunction with the estimation of the voltages and currents at the reach point is configured to determine a first matrix having matrix parameters determined on basis of the length of the transmission line, the line impedance and the shunt factor, and multiply the first matrix with a second matrix having matrix parameters based on the first phase voltages and first phase currents.

15. A non-transitory computer-readable medium having a computer program product stored thereon, the computer program product comprising instructions which, when downloaded into an intelligent electronic device (IED) connectable to a transmission line of a power transmission system, cause the intelligent electronic device to carry out operations comprising:
measuring values of first phase voltages and first phase currents at a first measurement point of the transmission line;
obtaining, for the transmission line from the first measurement point to a reach point at a distance from the IED, a shunt factor between the transmission line and ground;
estimating, for the reach point, voltage estimates and current estimates on basis of the first phase voltages, the first phase currents, and the shunt factor; and
determining whether a fault has occurred or not on basis of at least one of the voltage estimates and the current estimates.
